(19) United States
(12) Patent Application Publication
(10) Pub. No.: US 2025/0212528 A1
(43) Pub. Date: Jun. 26, 2025

(54) NONVOLATILE STORAGE DEVICE, AND NONVOLATILE STORAGE SYSTEM

(71) Applicant: SONY SEMICONDUCTOR SOLUTIONS CORPORATION, KANAGAWA (JP)

(72) Inventors: ISAO NARITAKE, KANAGAWA (JP); NOBUYUKI ISHIKAWA, KANAGAWA (JP); TOMOTSUNE KOYANAGI, KANAGAWA (JP); TOMOKO SHIMADA, KANAGAWA (JP); YOSHIHIKO KINOSHITA, KANAGAWA (JP); TETSUO MOTOMURA, KANAGAWA (JP); TSUKASA OJIRO, KANAGAWA (JP); KENICHI NAGAMATSU, KANAGAWA (JP); TAKANORI KURANO, KANAGAWA (JP); KAZUHIKO SHIMOYAMA, KANAGAWA (JP)

(21) Appl. No.: 18/848,684

(22) PCT Filed: Jan. 19, 2023
(86) PCT No.: PCT/JP2023/001481

§ 371 Date: Sep. 19, 2024

(30) Foreign Application Priority Data
Mar. 28, 2022 (JP) 2022-052415

(51) Int. Cl. H10D 89/60

(52) U.S. Cl. CPC H10D 89/814

(57) ABSTRACT

The present disclosure provides a nonvolatile storage device and a nonvolatile storage system capable of reducing at least either the current supply amount or the fluctuations when breakdown is to be caused simultaneously in a plurality of memory cells.

The nonvolatile storage device includes: a memory cell array including a plurality of first signal lines, a plurality of second signal lines intersecting the plurality of first signal lines, and a plurality of memory cells disposed at intersection portions between the plurality of first signal lines and the plurality of second signal lines; and a plurality of switching elements that put ends of the respective first signal lines of the plurality of first signal lines and a power supply into either a connected state or a disconnected state, in which two or more switching elements among the plurality of switching elements can be in the connected state simultaneously at a time of writing into the memory cell.

### TECHNICAL FIELD

The present disclosure relates to a nonvolatile storage device and a nonvolatile storage system.

### BACKGROUND ART

A nonvolatile storage device holds saved data when power supply is cut off. In general, memory cells are disposed at the respective intersection portions between a plurality of bit lines and a plurality of word lines, and are arranged in a matrix fashion. A voltage of several volts is applied to a thin insulating film in the storage element included in the memory cell, to cause electrical breakdown. Thus, data is stored.

### CITATION LIST

### Patent Document

Patent Document 1: Japanese Patent Application Laid-Open No. 2010-103563

### SUMMARY OF THE INVENTION

### Problems to be Solved by the Invention

Meanwhile, there is a demand for faster electrical breakdown. Therefore, attempts have been made to cause breakdown simultaneously in a plurality of memory cells arranged in a plurality of columns with respect to the word line in the same row. However, to cause breakdown simultaneously in a plurality of memory cells arranged in a plurality of columns in the same row, the amount of current to be supplied from the power supply might become insufficient or fluctuate.

Therefore, the present disclosure provides a nonvolatile storage device and a nonvolatile storage system capable of reducing at least either the current supply amount or the fluctuations when breakdown is to be caused simultaneously in a plurality of memory cells.

### Solutions to Problems

To solve the above problem, the present disclosure provides a nonvolatile storage device that includes:
a memory cell array including a plurality of first signal lines, a plurality of second signal lines intersecting the plurality of first signal lines, and a plurality of memory cells disposed at intersection portions between the plurality of first signal lines and the plurality of second signal lines; and
a plurality of switching elements that put each of ends of the plurality of first signal lines and a power supply into a connected state or a disconnected state,
in which two or more switching elements among the plurality of switching elements can be in the connected state simultaneously at a time of writing into the memory cell.

A first voltage may be supplied from the power supply to the plurality of switching elements when data is written into the memory cells, and a second voltage lower than the first voltage may be supplied from the power supply when data is read from the memory cells.

The plurality of first signal lines may include combinations of pairs of first signal lines, and two switching elements corresponding to a pair of first signal lines may be simultaneously put into a connected state at a time of writing into the memory cell.

The memory cell array may further include a plurality of third signal lines intersecting the plurality of second signal lines,
each memory cell of a plurality of the memory cells may include a storage element and a selection element,
in the storage element, the first signal line may be connected to the upper surface of an insulating film, and one end of the selection element may be connected to the lower surface of the insulating film, and
the selection element may have the other end connected to the third signal line, and the gate connected to the second signal line.

Each memory cell of a plurality of the memory cells may further include a protection element, and
one end of the protection element may be connected to at least the lower surface of the insulating film.

The memory cell array may further include a plurality of first signal lines, and a plurality of fourth signal lines intersecting the plurality of third signal lines, and
the gate of the protection element may be connected to the fourth signal line.

The other end of the protection element may be connected to the gate of the protection element.

To the lower surface of the insulating film on the one end side at which the one end of the selection element is connected to the lower surface of the insulating film,
the one end of the protection element may be connected to the other end side of the lower surface of the insulating film with respect to the one end side to be connected.

The one end of the protection element may be connected to the one end side at which the one end of the selection element is connected to the lower surface of the insulating film.

The memory cell array may further include a plurality of first signal lines, and a plurality of fifth signal lines intersecting the plurality of third signal lines, and the other end of the protection element may be connected to the fifth signal line.

When electrical breakdown of the storage element is to be prevented, the gate of the protection element may be supplied with a potential with which a differential pressure between the first voltage and the lower surface of the insulating film falls within a range that does not cause electrical breakdown of the storage element.

When electrical breakdown of the storage element is to be caused, the gate of the protection element may be supplied with a potential with which a differential pressure between the first voltage and the lower surface of the insulating film falls within a range that causes electrical breakdown of the storage element.

When electrical breakdown of the storage element is to be prevented, the protection element may be put into a connected state, and the fifth signal line may be supplied with a potential with which a differential pressure between the first voltage and the lower surface of the insulating film falls within a range that does not cause electrical breakdown of the storage element.

When data is to be written into the memory cell, the first voltage may be supplied from the power supply, and the selection element may be put into a connected state.

When data is to be read from the memory cell, the second voltage may be supplied from the power supply, and the selection element may be put into a connected state.

The nonvolatile storage device may further include
a signal reader circuit that outputs a first signal when a current is detected from the third signal line, and outputs a second signal when any current is not detected.

The insulating film may be a gate oxide film.

The protection element and the selection element may be MOS transistors.

To solve the above problem, the present disclosure provides a nonvolatile storage system that includes:
the nonvolatile storage device described above; and
a memory controller that controls voltages to be supplied to the plurality of first signal lines and the plurality of second signal lines.

The power supply may be further included.

### BRIEF DESCRIPTION OF DRAWINGS

FIG. 1 is a block diagram illustrating an example configuration of a nonvolatile storage system.

FIG. 2 is a block diagram illustrating an example configuration of a nonvolatile storage device according to the present embodiment.

FIG. 3 is a diagram schematically illustrating memory cells of a nonvolatile storage device.

FIG. 4 is a plan view illustrating the layout of part of a memory array.

FIG. 5 is a sectional view taken along the line A-A defined in FIG. 4.

FIG. 6 is a schematic diagram illustrating an example of an operation at a time of writing.

FIG. 7 is a schematic diagram illustrating an example of an operation at a time of reading.

FIG. 8 is a diagram schematically illustrating a nonvolatile storage device of a comparative example.

FIG. 9 is a diagram schematically illustrating memory cells of a nonvolatile storage device according to Modification 1.

FIG. 10 is a diagram schematically illustrating memory cells of a nonvolatile storage device according to Modification 2.

FIG. 11 is a diagram schematically illustrating memory cells of a nonvolatile storage device according to a second embodiment.

### MODE FOR CARRYING OUT THE INVENTION

The following is a description of embodiments of a nonvolatile storage device and a nonvolatile storage system, with reference to the drawings. Although the principal components of the nonvolatile storage device and the nonvolatile storage system will be mainly described below, a display apparatus may include components and functions that are not illustrated in the drawings or are not described. The following description does not exclude components and functions that are not illustrated in the drawings or are not described.

### First Embodiment

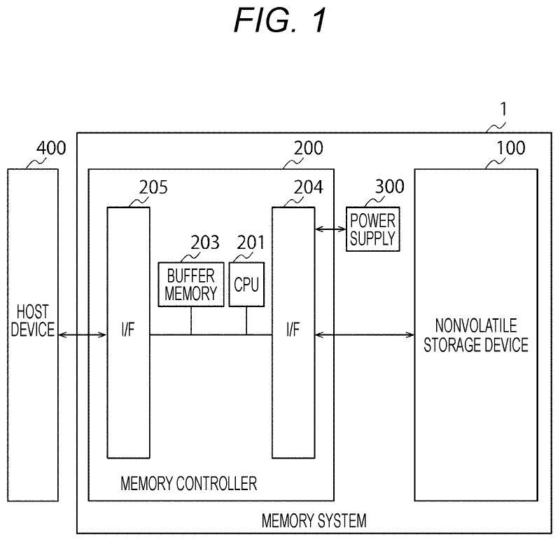

In the description below, a nonvolatile storage system 1 according to a first embodiment is described. FIG. 1 is a block diagram illustrating an example configuration of the nonvolatile storage system 1 including a nonvolatile storage device 100 according to the first embodiment.

The nonvolatile storage system 1 communicates with a host device 400, for example. The nonvolatile storage system 1 holds data from the host device 400, and also reads the data into the host device 400. As illustrated in FIG. 1, the nonvolatile storage system 1 includes the nonvolatile storage device 100, a memory controller 200, and a power supply 300.

The memory controller 200 controls the nonvolatile storage device 100 in accordance with an instruction from the host device 400. Specifically, the memory controller 200 writes data designated to be written into the nonvolatile storage device 100 by the host device 400, and reads data instructed to be read out from the nonvolatile storage device 100 by the host device 400 and transmits the data to the host device 400.

The nonvolatile storage device 100 includes a plurality of memory cells, and stores data in a nonvolatile manner. The nonvolatile storage device 100 and the power supply 300 are connected to the memory controller 200 via a bus.

The memory controller 200 includes a central processing unit (CPU) 201, a buffer memory 203, and a plurality of interface circuits 204 and 205. The CPU 201 controls the entire operation of the memory controller 200. For example, the CPU 201 issues a write command to the nonvolatile storage device 100 via the interface circuits 204 and 205, in response to a command to write data received from the host device 400. This operation is similar in the case of reading. Also, the memory controller 200 controls the power supply 300 to a voltage corresponding to the data write command, which is 5.2 volts, for example. Likewise, the memory controller 200 controls the power supply 300 to a voltage corresponding to the data read command, which is 2.2 volts, for example. The buffer memory 203 temporarily stores read data the memory controller 200 has received from the nonvolatile storage device 100, write data received from the host device 400, and the like.

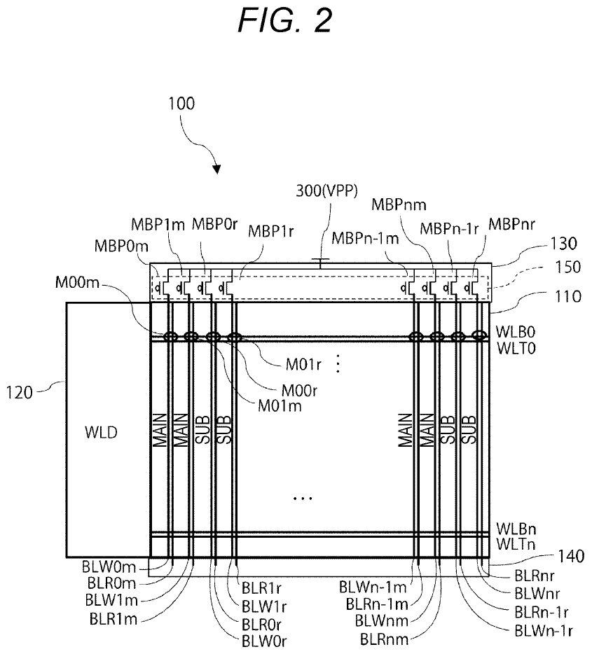

FIG. 2 is a block diagram illustrating an example configuration of the nonvolatile storage device 100 according to the present embodiment. As illustrated in FIG. 2, the nonvolatile storage device 100 includes a memory cell array 110, a word line control unit (WLD) 120, a bit line control unit 130, and a read circuit 140. In FIG. 2, a suffix “m” is added to the symbols corresponding to the main region, and a suffix “r” is added to the symbols corresponding to the sub region.

The memory cell array 110 is a MOS integrated circuit, for example, and includes a plurality of rows of word lines WLT0 to WLTn, a plurality of rows of protection lines WLB0 to WLBn, a plurality of columns of bit lines BLW0m to BLWnm in the main region, a plurality of columns of bit lines BLW0r to BLWnr in the sub region, a plurality of columns of source lines BLR0m to BLRnm in the main region, a plurality of columns of source lines BLR0r to BLRnr in the sub region, a plurality of memory cells M00m to Mnnm and M00r to Mnnr disposed at the intersection portions among the plurality of rows of word lines WLT0 to WLTn, the bit lines BLW0m to BLWnm, and the bit lines BLW0r to BLWnr. The memory cells M00m to Mnnm in the main region correspond to the memory cells M00r to Mnnr in the sub region, respectively. Although the plurality of memory cells M00m to Mnnm is described as n+1 rows and n+1 columns herein, and the plurality of memory cells M00r to Mnnr is described as n+1 rows and n+1 columns herein, the present disclosure is not limited to this, and any appropriate number of rows and columns may be used.

In the nonvolatile storage device 100 according to the present embodiment, simultaneous writing and reading can be performed on a plurality of memory cells Mz0m to Mznm and Mz0r to Mznr arranged in the same z row. Also, in the nonvolatile storage device 100 according to the present embodiment, the same data can be simultaneously written into a memory cell in the main region and the corresponding memory cell in the sub region. That is, when data is written into the memory cell array 110, the same data is simultaneously written into at least one memory cell in the main region and the one corresponding memory cell in the sub region. In other words, the bit lines BLW0m to BLWnm and the bit lines BLW0r to BLWnr are formed with a pair of corresponding bit lines. Note that the memory cell array 110 will be described later in detail.

The word line control unit (WLD) 120 includes a latch circuit, for example, at an end of each of the word lines WLT0 to WLTn in the plurality of rows and the protection lines WLB0 to WLBn in the plurality of rows. Under the control of the memory controller 200, the word line control unit (WLD) 120 selects the row on which writing or reading is to be performed, and supplies an ON signal or an OFF signal. For example, under the control of the memory controller 200, each latch circuit supplies a voltage of 1.8 volts, for example, as an ON signal to the signal line of the selected row. On the other hand, a voltage of 0.0 volts is applied as an OFF signal to the signal lines of the unselected rows. That is, a voltage of 1.8 volts is supplied to the word line corresponding to the selected row among the word lines WLT0 to WLTn in the plurality of rows, and a voltage of 0.0 volts is supplied to the word lines corresponding to the unselected rows. Note that these voltages are examples, and voltages are not limited to these voltages.

Further, at a time of writing, each latch circuit supplies a voltage of 1.8 volts, for example, as a protection signal to the signal line of an unselected row, under the control of the memory controller 200. On the other hand, a voltage of 0.0 volts is supplied as a write signal to the signal line of the selected row. That is, a voltage of 0.0 volts is supplied to the protection line corresponding to the selected row among the protection lines WLB0 to WLBn in the plurality of rows, and a voltage of 1.8 volts is supplied to the protection lines corresponding to the unselected rows.

Furthermore, at a time of reading, each latch circuit supplies a voltage of 0.0 volts to all of the protection lines WLB0 to WLBn, under the control of the memory controller 200.

The bit line control unit 130 includes a switching element unit 150. The switching element unit 150 includes switching elements MBP0m to MBPnm and MBP0r to MBPnr corresponding to the bit lines BLW0m to BLWnm and the bit lines BLW0r to BLWnr, respectively. One end of each of the switching elements MBP0m to MBPnm and MBP0r to MBPnr is connected to each corresponding one of the bit lines BLW0m to BLWnm and the bit lines BLW0r to BLWnr. On the other hand, the other end of each of the switching elements MBP0m to MBPnm and MBP0r to MBPnr is connected to the power supply (VPP) 300. Note that the power supply 300 may be formed with a plurality of independent power supplies.

The switching elements MBP0m to MBPnm and MBP0r to MBPnr are PMOS transistors, for example, and the gates thereof are connected to a control line of the memory controller 200. As a result, under the control of the memory controller 200, the bit lines BLW0m to BLWnm and the bit lines BLW0r to BLWnr are supplied with a voltage of 5.2 volts at a time of writing, and a voltage 2.2 volts at a time of reading, for example. The plurality of columns of source lines BLR0m to BLRnm is maintained at 0.0 volts as the ground potential, for example.

For example, in a case where simultaneous writing is to be performed on a plurality of columns, the switching elements corresponding to the columns on which the writing is to be performed among the switching elements MBP0m to MBPnm and MBP0r to MBPnr are put into a connected state. As a result, a voltage of 5.2 volts is supplied to the bit lines corresponding to the columns on which the writing is to be performed.

For example, in a case where simultaneous reading is to be performed on a plurality of columns, the switching elements corresponding to the columns on which the reading is to be performed among the switching elements MBP0m to MBPnm and MBP0r to MBPnr are put into a connected state. As a result, a voltage of 2.2 volts is supplied to the bit lines corresponding to the columns on which the reading is to be performed. Note that these voltages are examples, and voltages are not limited to these voltages.

In a case where simultaneous reading from a plurality of columns is performed, the read circuit 140 outputs a signal as “1” to the columns from which electric current is detected among the plurality of columns of source lines BLR0m to BLRnm in the main region and the plurality of columns of source lines BLR0r to BLRnr in the sub region. Meanwhile, in the case where simultaneous reading from a plurality of columns is performed, the read circuit 140 outputs a signal as “0” to the columns from which electric current is not detected among the plurality of columns of source lines BLR0m to BLRnm in the main region and the plurality of columns of source lines BLR0r to BLRnr in the sub region.

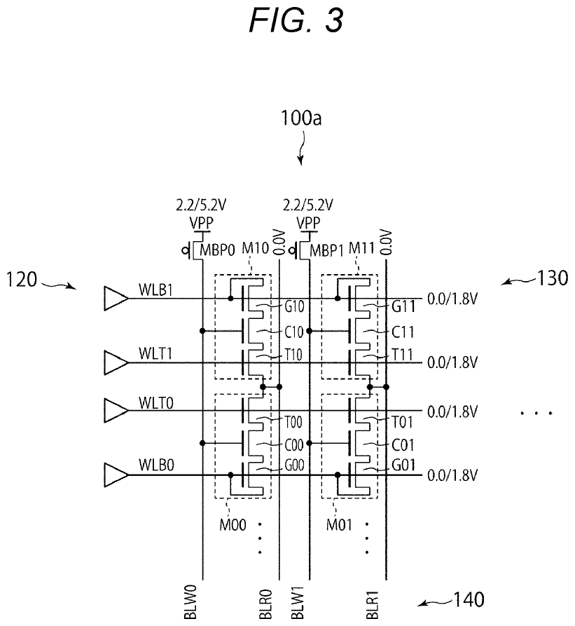

FIG. 3 is a diagram schematically illustrating memory cells of a nonvolatile storage device 100a. Memory cells M00 to M11 of two rows and two columns in the main region are illustrated herein, but the other memory cells have a similar configuration. Further, for ease of explanation, the suffixes “r” and “m” are omitted.

The memory cell M10 includes MOS transistors T10, G10, and C10. That is, the MOS transistor T10 is an NMOS transistor, for example, the source as one end of the MOS transistor T10 is connected to the source line BLR0, and the drain as the other end is connected to one end of the MOS transistor C10. Furthermore, the gate of the MOS transistor T10 is connected to the word line WLT1. The MOS transistor T10 is referred to as a selection element in some cases. That is, the MOS transistor T10 is used to select the memory cell M10 and perform writing or reading.

The other end of the MOS transistor C10 is connected to one end of the MOS transistor G10. Further, the gate of the MOS transistor C10 is connected to the bit line BLW0. The MOS transistor C10 is referred to as a storage element in some cases.

The MOS transistor G10 is an NMOS transistor, for example, and the source as one end is connected to the other end of the MOS transistor C10 as described above. The drain as the other end is connected to the protection line WLB1 and the gate. This MOS transistor G10 is connected by so-called diode connection, and is referred to as a protection element in some cases. That is, the MOS transistor G10 is used to protect the MOS transistor C10 so that writing is not performed on the MOS transistor C10 in a case where the memory cell M10 is unselected while writing is performed on the other memory cells in the same column.

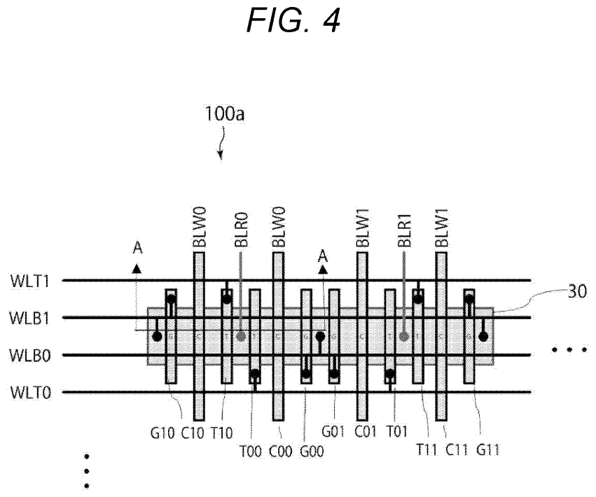

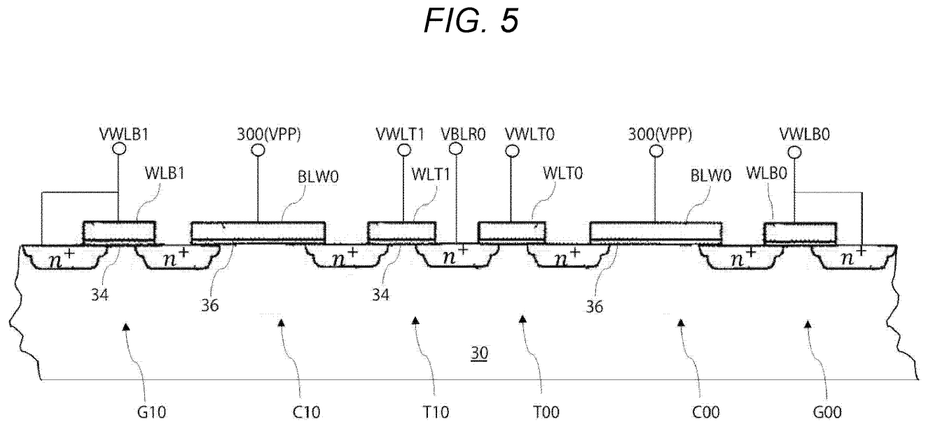

FIG. 4 is a plan view illustrating the layout of part of a memory array 100a. FIG. 5 is a sectional view taken along the line A-A defined in FIG. 4. As illustrated in FIG. 4, the word lines WLT0 to WLTn of the plurality of rows and the protection lines WLB0 to WLBn of the plurality of rows are orthogonal to the bit lines BLW0m to BLWnm, the bit lines BLW0r to BLWnr of the plurality of columns in the sub region, the source lines BLR0m to BLRnm of the plurality of columns in the main region, and the source lines BLR0r to BLRnr of the plurality of columns in the sub region. A region 30 is a p-well active region, for example.

As illustrated in FIG. 5, a thin gate oxide film layer 34 is formed on the lower surfaces of the protection lines WLB1 and WLB0 of the MOS transistors G10 and G00. The source and drain regions of the MOS transistors G10 and G00 are formed with N-type lightly doped drains as n+ regions. The n+ regions on the source side of the MOS transistors G10 and G00 are 0.6 volts lower in potential than the n+ regions on the drain side, for example, due to so-called diode connection. Voltages VWLB1 and VWLB0 are applied to the protection lines WLB1 and WLB0, respectively. As described above, the voltages VWLB1 and VWLB0 are 0.0 volts or 1.8 volts, for example, in the present embodiment. The thickness of the thin gate oxide film layer 34 is 10 to 50 angstroms, for example.

A thin gate oxide film layer 36 is formed on the lower surfaces of the bit lines BLW0 and BLW1 of the MMOS transistors C10 and C00. The thickness of the thin gate oxide film layer 36 is 10 to 50 angstroms, for example. The thin gate oxide film layer 36 may be formed to be thinner than the thin gate oxide film layer 34, for example. With this arrangement, breakdown of the thin gate oxide film layer 34 is prevented when electrical breakdown is caused in the thin gate oxide film layer 36. The voltage VPP is applied to each of the bit lines BLW0 and BLW1. As described above, in the present embodiment, the voltage VPP is 2.2 volts at a time of reading, and is 5.2 volts at a time of writing, for example. The electric breakdown potential of the thin gate oxide film layer 36 is set to 4.8 volts, for example. The thin gate oxide film layer 36 is only required to be a film-like member that is capable of breakdown by application of a predetermined voltage, and is not necessarily an oxide film. For example, it may be a dielectric material of such a type as a nitride film.

The thin gate oxide film layer 34 is formed on the lower surfaces of the word lines WLT1 and WLT0 of the MOS transistors T10 and T00. The source and drain regions of the MOS transistors T10 and T00 are formed with N-type lightly doped drains as n+ regions. The source line BLR0 is electrically connected to the n+ regions on the source side of the MOS transistors T10 and T00. As described above, the source line BLR0 has the ground potential, which is 0.0 volts, for example.

Voltages VWLT1 and VWLT0 are applied to the word lines WLT1 and WLT0, respectively. The voltages VWLT1 and VWLT are 0.0 volts or 1.8 volts as described above in the present embodiment, for example.

As described above, in the NMOS transistors C10 and C00, the bit lines BLW0 and BLW1 are connected to the upper surface of the thin gate oxide film layer 36, and the n+ regions on the drain side of the MOS transistors T10 and T00 are connected to the lower surface of the thin gate oxide film layer 36. Likewise, the n+ regions on the source side of the MOS transistors G10 and G00 are connected to the lower surface of the thin gate oxide film layer 36.

### (Example of Write Operation)

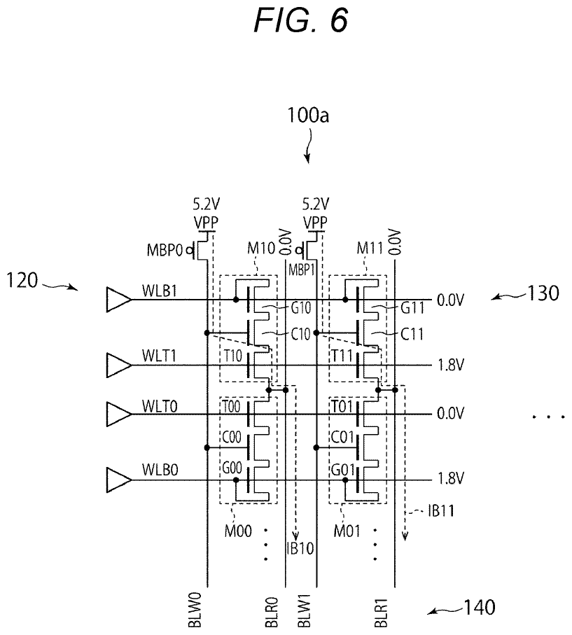

FIG. 6 is a schematic diagram illustrating an example of an operation at a time of writing. In a case where writing is to be performed, the memory controller 200 sets the voltage VPP to 5.2 volts, which is a high potential, and puts the switching elements corresponding to the column on which writing is to be performed among the switching elements MBP0m to MBPnm and MBP0r to MBPnr into a connected state.

Further, the memory controller 200 supplies 1.8 volts, which corresponds to a high-level signal, to the word line corresponding to the row on which writing is to be performed among the word lines WLT0 to WLTn. Furthermore, the memory controller 200 supplies 0.0 volts, which corresponds to a low-level signal (write signal), to the protection line corresponding to the row on which writing is to be performed among the protection lines WLB0 to WLBn. Meanwhile, 1.8 volts, which corresponds to a high-level signal (protection signal), is supplied to the protection lines corresponding to the rows on which writing is not to be performed among the protection lines WLB0 to WLBn.

As described above, the bit line control unit 130 includes the switching elements MBP0m to MBPnm and MBP0r to MBPnr, and is designed to be able to supply the voltage VPP to the corresponding bit lines BLW0m to BLWnm and the bit lines BLW0r to BLWnr. With this arrangement, it is possible to perform writing simultaneously on a plurality of columns of memory cells Mn0 to Mnn in the n rows, for example. In this case, writing is performed on one memory cell in each column, and accordingly, fluctuations in the currents flowing in the bit lines BLW0m to BLWnm and the bit lines BLW0r to BLWnr are reduced. In other words, even when writing is performed simultaneously on the plurality of columns of memory cells Mn0 to Mnn in the n rows, or even when writing is performed on the memory cells in one column in the n rows, the currents flowing in the bit lines BLW0m to BLWnm and the bit lines BLW0r to BLWnr on which writing is performed can be adjusted to the same current amount.

More specifically, in FIG. 6, writing into the memory cells M10 and M11 in the first row is simultaneously performed. On the other hand, writing into the memory cells M00 and M01 in the rows other than the first row, such as the zeroth row, for example, is not performed in this state.

In a case where writing is to be performed, the voltage VPP is set to 5.2 volts. The switching elements MBP0 and MBP1 corresponding to the bit lines BLW0 and BLW1 of the memory cells M10 and M11 on which writing is to be performed are then put into a connected state.

Also, the potential of the protection line WLB1 of the memory cells M10 and M11 on which writing is to be performed is set to 0.0 volts.

Further, the potential of the word line WLT1 of the memory cells M10 and M11 on which writing is to be performed is set to 1.8 volts. As a result, the MOS transistors T10 and T11 electrically connect each of the source lines BLR0 and BLR1 to each corresponding one end of the NMOS transistors C10 and C11. Thus, a voltage of 5.2 volts is applied to the thin gate oxide film layer 36 of the NMOS transistors C10 and C11, for example, and electrical breakdown occurs.

Meanwhile, the switching elements MBP0 and MBP1 corresponding to the bit lines BLW0 and BLW1 are also in a connected state in the memory cells M00 and M01 in which writing has not performed on the zeroth row. Note that the switching elements of the bit lines on which writing is not to be performed are maintained in a disconnected state.

Further, the potential of the protection line WLB0 of the memory cells M00 and M01 is set to 1.8 volts. As a result, the source regions of the MOS transistors G00 and G01 have 1.2 volts, for example.

Furthermore, the potential of the word line WLT0 of the memory cells M00 and M01 is set to 0.0 volts. As a result, the MOS transistors T00 and T01 maintain each of the source lines BLR0 and BLR1 and each corresponding one end of the NMOS transistors C00 and C01 in an electrically disconnected state. Thus, a voltage of 4.0 volts is applied to the thin gate oxide film layer 36 of the NMOS transistors C00 and C01, for example, and electrical breakdown occurs.

As described above, in a case where electrical breakdown of the memory cells M10 and M11 in the plurality of columns is caused, the potential immediately below the thin gate oxide film layer 36 of the MOS transistors C00 and C01 is also increased 1.6 volts by the MOS transistors G00 and G01. Thus, electrical breakdown of the thin gate oxide film layer 36 of the MOS transistors C10 and C11 is prevented.

### (Example of Read Operation)

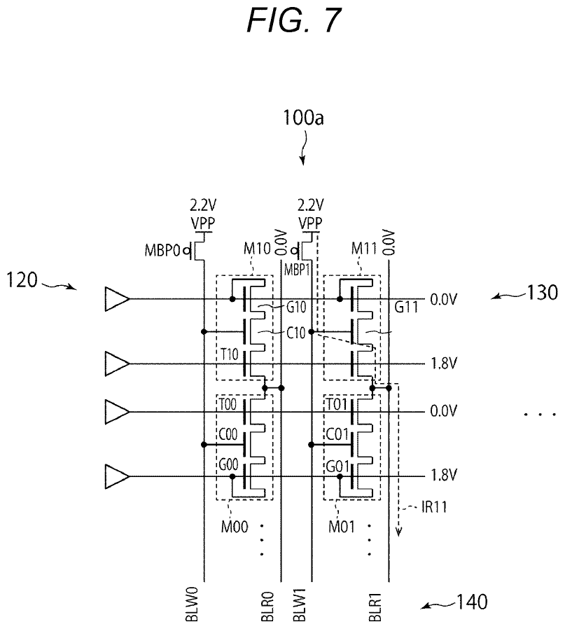

FIG. 7 is a diagram illustrating an example of an operation at a time of reading. In a case where reading is to be performed, the memory controller 200 sets the voltage VPP to 2.2 volts, which is a low potential, and puts the switching elements corresponding to the column on which reading is to be performed among the switching elements MBP0m to MBPnm and MBP0r to MBPnr into a connected state.

Further, the memory controller 200 supplies 1.8 volts, which corresponds to a high-level signal, to the word line corresponding to the row on which reading is to be performed among the word lines WLT0 to WLTn. Further, the memory controller 200 supplies 0.0 volts, which corresponds to a low-level signal, to all the protection lines WLB0 to WLBn. On the other hand, 0.0 volts, which corresponds to a low-level signal, is supplied to the word line corresponding to the row on which reading is not to be performed among the word lines WLT0 to WLTn.

More specifically, in FIG. 7, writing is performed only on the memory cell M11 in the first row. That is, an example in which electrical breakdown is caused only in the memory cell M11 is described herein. Reading from the memory cells M10 and M11 in the first row is simultaneously performed. On the other hand, reading from the memory cells M00 and M01 in the rows other than the first row, such as the zeroth row, for example, is not performed in this state.

In a case where reading is to be performed, the memory controller 200 sets the voltage VPP to 2.2 volts. The memory controller 200 then puts the switching elements MBP0 and MBP1 corresponding to the bit lines BLW0 and BLW1 of the memory cells M10 and M11 on which reading is to be performed, into a connected state.

Also, the memory controller 200 sets the potentials of the word lines WLT1 and WLT0 of the memory cells M10 and M11 on which reading is to be performed, to 1.8 volts. As a result, the MOS transistors T10 and T11 electrically connect each of the source lines BLR0 and BLR1 to each corresponding one end of the MOS transistors C10 and C11. Further, a voltage of 2.2 volts is applied to the thin gate oxide film layer 36 of the MOS transistors C10 and C11, for example. Since the thin gate oxide film layer 36 of the MOS transistor C11 has electrical breakdown, it is possible to detect a current from the source line BLR1.

On the other hand, since the thin gate oxide film layer 36 of the MOS transistor C10 on which writing has not been performed does not have electrical breakdown, it is not possible to detect a current from the source line BLR0. For example, the read circuit 140 outputs “1” as a signal corresponding to the column of the MOS transistor C11 that has electrical breakdown, and outputs “0” as a signal corresponding to the column of the MOS transistor C10 that does not have electrical breakdown.

On the other hand, 0.0 volts corresponding to a low-level signal is supplied to the word line WLT0 of the row that is not being read. Therefore, the MOS transistors T00 and T01 are electrically disconnected from the source lines BLR0 and BLR1, and any current is not detected from the memory cells M00 and M01. In this manner, data can be read simultaneously from the memory cells M10 and M11 of a plurality of columns in the same row.

### COMPARATIVE EXAMPLES

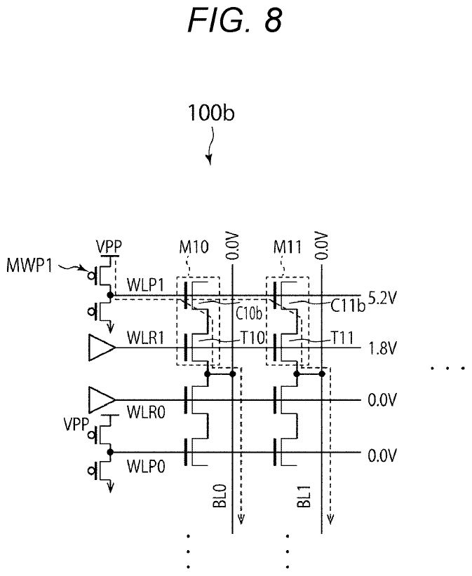

FIG. 8 is a diagram schematically illustrating a nonvolatile storage device 100b of a comparative example. The nonvolatile storage device 100b includes word lines WLR0 to WLRn in the row direction, power supply lines WLP0 to WLPn in the row direction, source lines BL0 to BLn, and memory cells M00 to Mnn at the intersection portions between the word lines WLR0 to WLRn and the source lines BL0 to BLn. Only the operations of the power supply lines WLP0 to WLPn at a time of writing are described herein in a simplified manner.

The memory cell M10 includes a MOS transistor T10 and a MOS transistor C10b. One end of the MOS transistor T10 is connected to the source line BL0, and the other end is connected to one end of the MOS transistor C10b. The gate of the MOS transistor T10 is connected to the word line WLR1. The power supply line WLP1 is connected to the gate of the MOS transistor C10b. The other memory cells have a configuration similar to the above.

For example, to perform writing on the memory cells M10 and M11 in the first row, a potential of 5.2 volts is supplied from a switching element MWP1 connected to one end of the power supply line WLP0. As a result, a potential of 5.2 volts is supplied to the MOS transistors of the plurality of columns on which writing is to be performed, and breakdown occurs.

In the comparative example, however, the voltage VPP is supplied from one end of the power supply line WLP0. Therefore, it is necessary to increase the current to be supplied from one end of the power supply line WLP1, as the number of memory cells to have breakdown at the same time increases. To prevent such a phenomenon, it is necessary to have a current supply capability with which the influence of connection of the signal lines corresponding to a plurality of bits on which writing is to be performed to the power supply line WLP1 can be reduced.

Further, the MOS transistors of the signal lines corresponding to the plurality of bits break at various timings. As the number of written bits (signal lines on which writing is performed) increases, the power supply line WLP1 has a current drop (IR-Drop), and the write characteristics become unstable. On the other hand, the nonvolatile storage device 100a according to the present embodiment includes the switching elements (PMOS transistors (see FIG. 2)) that drive the write current for the respective columns. Accordingly, each switching element is only required to be capable of supplying a current for 1-bit writing, and the influence of the write timings of the other bits is also reduced.

As described above, the nonvolatile storage device 100a according to the present embodiment includes the switching elements MBP0m to MBPnm and MBP0r to MBPnr (see FIG. 2) that drive the write current for each of the bit lines BLW0m to BLWnm and the bit lines BLW0r to BLWnr. Thus, each of the switching elements MBP0m to MBPnm and MBP0r to MBPnr is only required to be capable of supplying a current for 1-bit writing, and the influence of the write timings of the other bits is also reduced.

### (Modification 1 of the First Embodiment)

A nonvolatile storage device 100c according to Modification 1 of the first embodiment differs from the nonvolatile storage device 100a according to the first embodiment in that MOS transistors T and G and MOS transistors C in a plurality of memory cells M00m to Mnnm and M00r to Mnnr have a different layout from that of the first embodiment. In the description below, differences from the nonvolatile storage device 100a according to the first embodiment are explained.

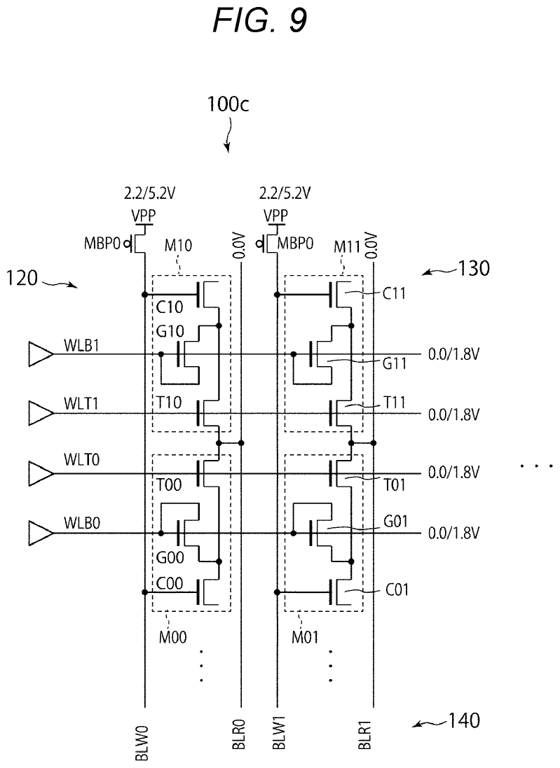

FIG. 9 is a diagram schematically illustrating memory cells of the nonvolatile storage device 100c according to Modification 1 of the first embodiment. Memory cells M00 to M11 of two rows and two columns in the main region are illustrated herein, but the other memory cells have a similar configuration. Further, for ease of explanation, the suffixes “r” and “m” are omitted.

As illustrated in FIG. 9, the memory cell M10 includes MOS transistors T10 and G10, and a MOS transistor C10. That is, the MOS transistor T10 is an NMOS transistor, for example, the source as one end of the MOS transistor T10 is connected to the source line BLR0, and the drain as the other end is connected to the source as one end of the MOS transistor G10 and one end of the MOS transistor C10. Furthermore, the gate of the MOS transistor T10 is connected to the word line WLT1.

The source as one end of the MOS transistor G10 is connected to the other end of the MOS transistor T10 as described above. The drain as the other end is connected to the protection line WLB1 and the gate. Further, the gate of the MOS transistor C10 is connected to the bit line BLW0.

With such a layout, in a case where writing into the MOS transistor C10 is protected, the potential of the MOS transistor C10 can be controlled only with the potential of the source region of the MOS transistor G10, and the write protection is more stable.

### (Modification 2 of the First Embodiment)

A nonvolatile storage device 100d according to Modification 2 of the first embodiment differs from the nonvolatile storage device 100c according to the first embodiment in that MOS transistors T and G and MOS transistors C in a plurality of memory cells M00m to Mnnm and M00r to Mnnr have a different layout, and the drain and the gate of each MOS transistor G are connected to different wiring lines. In the description below, differences from the nonvolatile storage device 100c according to the first embodiment are explained.

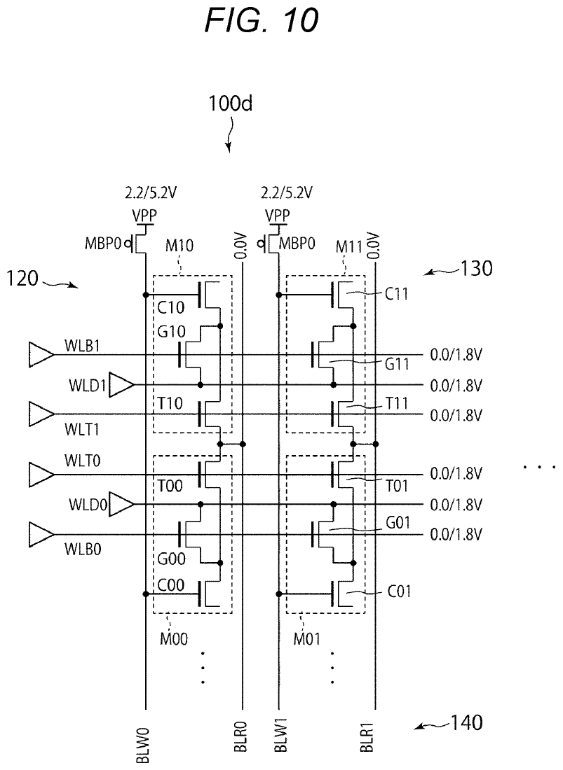

FIG. 10 is a diagram schematically illustrating memory cells of the nonvolatile storage device 100d according to Modification 2 of the first embodiment. Memory cells M00 to M11 of two rows and two columns in the main region are illustrated herein, but the other memory cells have a similar configuration. Further, for ease of explanation, the suffixes “r” and “m” are omitted.

As illustrated in FIG. 10, the memory cell M10 includes MOS transistors T10 and G10, and a MOS transistor C10. That is, the MOS transistor T10 is an NMOS transistor, for example, the source as one end of the MOS transistor T10 is connected to the source line BLR0, and the drain as the other end is connected to the source as one end of the MOS transistor G10 and one end of the MOS transistor C10. Furthermore, the gate of the MOS transistor T10 is connected to the word line WLT1. Further, the nonvolatile storage device 100d includes drain lines WLD0 to WLDn.

The source as one end of the MOS transistor G10 is connected to the other end of the MOS transistor T10 as described above. The drain as the other end is connected to the drain line WLD1, and the gate is connected to the protection line WLB1. Further, the gate of the MOS transistor C10 is connected to the bit line BLW0. At a time of writing into the MOS transistor C10, the gate of the MOS transistor G10 is supplied with 1.8 volts, which is a high-level signal. Meanwhile, the drain of the MOS transistor G10 is supplied with 0.0 volts, which is a low-level signal. As a result, electrical breakdown occurs in the MOS transistor C10.

In a case where writing into the MOS transistor C10 is protected, on the other hand, the gate of the MOS transistor G10 is supplied with 1.8 volts, which is a high-level signal. Meanwhile, the drain of the MOS transistor G10 is supplied with 1.8 volts, which is a high-level signal. Thus, electrical breakdown of the MOS transistor C10 is prevented.

With such a layout, in a case where writing into the MOS transistor C10 is protected, the potential of the MOS transistor C10 can be controlled only with the potential of the source region of the MOS transistor G10, and the write protection is more stable. Furthermore, a potential equivalent to the potential of the source region of the MOS transistor G10 can be applied as the potential of the MOS transistor C10, and thus, the write protection can be controlled more accurately.

### Second Embodiment

A nonvolatile storage device 100e according to a second embodiment differs from the nonvolatile storage device 100a according to the first embodiment in not including the MOS transistors G in the plurality of memory cells M00m to Mnnm and M00r to Mnnr. In the description below, differences from the nonvolatile storage device 100a according to the first embodiment are explained.

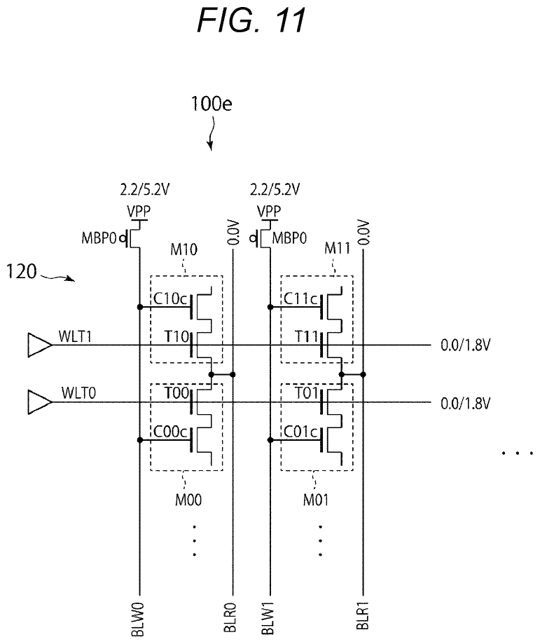

FIG. 11 is a diagram schematically illustrating memory cells of the nonvolatile storage device 100e according to the second embodiment. Memory cells M00 to M11 of two rows and two columns in the main region are illustrated herein, but the other memory cells have a similar configuration. Further, for ease of explanation, the suffixes “r” and “m” are omitted.

As illustrated in FIG. 11, the memory cell M10 includes a MOS transistor T10 and a MOS transistor C10c. A thin gate oxide film layer 34 of the MOS transistor T10 is designed to be thicker than the thin gate oxide film layer 34 of the MOS transistor T10 according to the first embodiment (see FIG. 5).

The MOS transistor T10 is an NMOS transistor, for example, the source as one end of the MOS transistor T10 is connected to the source line BLR0, and the drain as the other end is connected to one end of the MOS transistor C10. Furthermore, the gate of the MOS transistor T10 is connected to the word line WLT1.

Further, the gate of the MOS transistor C10 is connected to the bit line BLW0. At a time of writing into the MOS transistor C10, the VPP voltage is set to 5.2 volts, and the gate of the MOS transistor T10 is supplied with 1.8 volts, which is a high-level signal. As a result, a voltage of 5.2 is applied to the MOS transistor C10, and electrical breakdown occurs.

In a case where writing into the MOS transistor C10 is protected, on the other hand, the gate of the MOS transistor T10 is supplied with 0.0 volts, which is a low-level signal. As a result, the MOS transistor C10 is electrically disconnected from the source line BLR0, and a voltage of lower than 4.8 volts is applied thereto. Thus, electrical breakdown of the MOS transistor C10 is prevented.

Further, at a time of reading from the MOS transistor C10, the VPP voltage is set to 2.2 volts, and the gate of the MOS transistor T10 is supplied with 1.8 volts, which is a high-level signal. As a result, electrical breakdown occurs in the MOS transistor C10, and thus, an electrical signal can be detected from the source line BLR0. In a case where the MOS transistor C10 does not have electrical breakdown, the insulated state of the thin gate oxide film layer 36 is maintained, and any electrical signal is not detected.

As described above, in the nonvolatile storage device 100e according to the present embodiment, the thin gate oxide film layer 34 is designed to be thicker than the thin gate oxide film layer 36. With this arrangement, not only can effects similar to those of the nonvolatile storage device 100a according to the first embodiment be achieved, but the plurality of memory cells M00m to Mnnm and M00r to Mnnr can be formed with the MOS transistors T and the MOS transistors Cc.

Note that the present technology may have configurations described below.
(1)

A nonvolatile storage device including:
a memory cell array including a plurality of first signal lines, a plurality of second signal lines intersecting the plurality of first signal lines, and a plurality of memory cells disposed at intersection portions between the plurality of first signal lines and the plurality of second signal lines; and
a plurality of switching elements that put each of ends of the plurality of first signal lines and a power supply into a connected state or a disconnected state,
in which two or more switching elements among the plurality of switching elements can be in the connected state simultaneously at a time of writing into the memory cell.
(2)

The nonvolatile storage device according to (1), in which a first voltage is supplied from the power supply to the plurality of switching elements when data is written into the memory cells, and a second voltage lower than the first voltage is supplied from the power supply when data is read from the memory cells.
(3)

The nonvolatile storage device according to (1), in which the plurality of first signal lines includes combinations of pairs of first signal lines, and two switching elements corresponding to a pair of first signal lines are simultaneously put into a connected state at a time of writing into the memory cell.
(4)

The nonvolatile storage device according to (2), in which the memory cell array further includes a plurality of third signal lines intersecting the plurality of second signal lines,
each memory cell of a plurality of the memory cells includes a storage element and a selection element,
in the storage element, the first signal line is connected to an upper surface of an insulating film, and one end of the selection element is connected to a lower surface of the insulating film, and
the selection element has another end connected to the third signal line, and a gate connected to the second signal line.
(5)

The nonvolatile storage device according to (4), in which
each memory cell of a plurality of the memory cells further includes a protection element, and
one end of the protection element is connected to at least the lower surface of the insulating film.
(6)

The nonvolatile storage device according to (5), in which
the memory cell array further includes a plurality of first signal lines, and a plurality of fourth signal lines intersecting the plurality of third signal lines, and
a gate of the protection element is connected to the fourth signal line.
(7)

The nonvolatile storage device according to (6), in which another end of the protection element is connected to the gate of the protection element.
(8)

The nonvolatile storage device according to (7), in which,
to the lower surface of the insulating film on the one end side at which the one end of the selection element is connected to the lower surface of the insulating film,
the one end of the protection element is connected to another end side of the lower surface of the insulating film with respect to the one end side to be connected.
(9)

The nonvolatile storage device according to (7), in which the one end of the protection element is connected to the one end side at which the one end of the selection element is connected to the lower surface of the insulating film.
(10)

The nonvolatile storage device according to (6), in which
the memory cell array further includes a plurality of first signal lines, and a plurality of fifth signal lines intersecting the plurality of third signal lines, and
another end of the protection element is connected to the fifth signal line.
(11)

The nonvolatile storage device according to (7), in which, when electrical breakdown of the storage element is to be prevented, the gate of the protection element is supplied with a potential with which a differential pressure between the first voltage and the lower surface of the insulating film falls within a range that does not cause electrical breakdown of the storage element.
(12)

The nonvolatile storage device according to (7), in which, when electrical breakdown of the storage element is to be caused, the gate of the protection element is supplied with a potential with which a differential pressure between the first voltage and the lower surface of the insulating film falls within a range that causes electrical breakdown of the storage element.
(13)

The nonvolatile storage device according to (10), in which, when electrical breakdown of the storage element is to be prevented, the protection element is put into a connected state, and the fifth signal line is supplied with a potential with which a differential pressure between the first voltage and the lower surface of the insulating film falls within a range that does not cause electrical breakdown of the storage element.
(14)

The nonvolatile storage device according to (4), in which, when data is to be written into the memory cell, the first voltage is supplied from the power supply, and the selection element is put into a connected state.
(15)

The nonvolatile storage device according to (14), in which, when data is to be read from the memory cell, the second voltage is supplied from the power supply, and the selection element is put into a connected state.
(16)

The nonvolatile storage device according to (15), further including
a signal reader circuit that outputs a first signal when a current is detected from the third signal line, and outputs a second signal when no current is detected.
(17)

The nonvolatile storage device according to (4), in which the insulating film is a gate oxide film.
(18)

The nonvolatile storage device according to (5), in which the protection element and the selection element are MOS transistors.
(19)

A nonvolatile storage system including:
the nonvolatile storage device according to (1); and
a memory controller that controls voltages to be supplied to the plurality of first signal lines and the plurality of second signal lines.
(20)

The nonvolatile storage system according to (19), further including the power supply.

Aspects of the present disclosure are not limited to the above-described individual embodiments, but include various modifications that can be conceived by those skilled in the art, and the effects of the present disclosure are not limited to those described above. That is, various additions, modifications, and partial deletions are possible without departing from the conceptual idea and spirit of the present disclosure derived from the matters defined in the claims and equivalents thereof.

### REFERENCE SIGNS LIST

1 Nonvolatile storage system
36 Thin gate oxide film layer
100a to 100e Nonvolatile storage device
110 Memory cell array
140 Read circuit
200 Memory controller
300 Power supply
BLW0m to BLWnm, BLW0r to BLWnr Bit line (first signal line)
BLR0m to BLRnm, BLR0r to BLRnr Source line (third signal line)
C MOS transistor (storage element)
G MOS transistor (protection element)
T MOS transistor (selection element)
M00m to Mnnm, M00r to Mnnr Memory cell
MBP0m to MBPnm, MBP0r to MBPnr Switching element
WLT0 to WLTn Word line (second signal line)
WLD0 to WLDn Drain line (fifth signal line)
WLB0 to WLBn Protection line (fourth signal line)

1. A nonvolatile storage device comprising:
a memory cell array including a plurality of first signal lines, a plurality of second signal lines intersecting the plurality of first signal lines, and a plurality of memory cells disposed at intersection portions between the plurality of first signal lines and the plurality of second signal lines; and
a plurality of switching elements that put each end of the respective first signal lines of the plurality of first signal lines and a power supply into one of a connected state or a disconnected state,
wherein at least two switching elements among the plurality of switching elements can be in the connected state simultaneously at a time of writing into the memory cell.

2. The nonvolatile storage device according to claim 1, wherein a first voltage is supplied from the power supply to the plurality of switching elements when data is written into the memory cells, and a second voltage lower than the first voltage is supplied from the power supply when data is read from the memory cells.

3. The nonvolatile storage device according to claim 1, wherein the plurality of first signal lines includes combinations of pairs of first signal lines, and two switching elements corresponding to a pair of first signal lines are simultaneously put into a connected state at a time of writing into the memory cell.

4. The nonvolatile storage device according to claim 2, wherein
the memory cell array further includes a plurality of third signal lines intersecting the plurality of second signal lines,
each memory cell of a plurality of the memory cells includes a storage element and a selection element,
in the storage element, the first signal line is connected to an upper surface of an insulating film, and one end of the selection element is connected to a lower surface of the insulating film, and
the selection element has another end connected to the third signal line, and a gate connected to the second signal line.

5. The nonvolatile storage device according to claim 4, wherein
each memory cell of a plurality of the memory cells further includes a protection element, and
one end of the protection element is connected to at least the lower surface of the insulating film.

6. The nonvolatile storage device according to claim 5,
wherein
the memory cell array further includes a plurality of first signal lines, and a plurality of fourth signal lines intersecting the plurality of third signal lines, and
a gate of the protection element is connected to the fourth signal line.

7. The nonvolatile storage device according to claim 6, wherein another end of the protection element is connected to the gate of the protection element.

8. The nonvolatile storage device according to claim 7, wherein,
to the lower surface of the insulating film on one end side at which the one end of the selection element is connected to the lower surface of the insulating film,
the one end of the protection element is connected to another end side of the lower surface of the insulating film with respect to the one end side to be connected.

9. The nonvolatile storage device according to claim 7, wherein the one end of the protection element is connected to the one end side at which the one end of the selection element is connected to the lower surface of the insulating film.

10. The nonvolatile storage device according to claim 6, wherein
the memory cell array further includes a plurality of first signal lines, and a plurality of fifth signal lines intersecting the plurality of third signal lines, and
another end of the protection element is connected to the fifth signal line.

11. The nonvolatile storage device according to claim 7, wherein, when electrical breakdown of the storage element is to be prevented, the gate of the protection element is supplied with a potential with which a differential pressure between the first voltage and the lower surface of the insulating film falls within a range that does not cause electrical breakdown of the storage element.

12. The nonvolatile storage device according to claim 7, wherein, when electrical breakdown of the storage element is to be caused, the gate of the protection element is supplied with a potential with which a differential pressure between the first voltage and the lower surface of the insulating film falls within a range that causes electrical breakdown of the storage element.

13. The nonvolatile storage device according to claim 10, wherein, when electrical breakdown of the storage element is to be prevented, the protection element is put into a connected state, and the fifth signal line is supplied with a potential with which a differential pressure between the first voltage and the lower surface of the insulating film falls within a range that does not cause electrical breakdown of the storage element.

14. The nonvolatile storage device according to claim 4, wherein, when data is to be written into the memory cell, the first voltage is supplied from the power supply, and the selection element is put into a connected state.

15. The nonvolatile storage device according to claim 14, wherein, when data is to be read from the memory cell, the second voltage is supplied from the power supply, and the selection element is put into a connected state.

16. The nonvolatile storage device according to claim 15, further comprising
a signal reader circuit that outputs a first signal when a current is detected from the third signal line, and outputs a second signal when no current is detected.

17. The nonvolatile storage device according to claim 4, wherein the insulating film includes a gate oxide film.

18. The nonvolatile storage device according to claim 5, wherein the protection element and the selection element include MOS transistors.

19. A nonvolatile storage system comprising:
the nonvolatile storage device according to claim 1; and
a memory controller that controls voltages to be supplied to the plurality of first signal lines and the plurality of second signal lines.

20. The nonvolatile storage system according to claim 19, further comprising the power supply.
